(19) United States
(12) Patent Application Publication
(10) Pub. No.: US 2005/0077080 A1
(43) Pub. Date: Apr. 14, 2005

(54) Ball grid array (BGA) package having corner or edge tab supports

(76) Inventors: Adesoji Dairo, Macungie, PA (US); Jeffery J. Gilbert, Schwenksville, PA (US); Christopher Horvath, Allentown, PA (US); Richard Lawrence Shook, Fogelsville, PA (US); Ebyson Thomas, Allentown, PA (US); Brian Thomas Vaccaro, Mertztown, PA (US)

Correspondence Address: MANELLI DENISON & SELTER PLLC, 7th Floor, 2000 M Street, N.W., Washington, DC, 20036-3307, US

(21) Appl. No.: 10/682,969

(22) Filed: Oct. 14, 2003

(51) Int. Cl. H05K 7/06

(52) U.S. Cl. 174/255; 361/804; 174/260; 257/778

(57) ABSTRACT

The present invention includes tab supports on the solder ball side of a BGA package substrate. The tab supports are preferably sized in a height direction to avoid or prevent a warped corner or edge of a BGA substrate from excessively pressing down on the solder balls when warping occurs, most often during the high temperature solder-reflow process. Exemplary tab supports comprise small standoff tabs placed in all four corners of the lower substrate of a BGA package, and/or on all four edges of the lower substrate. The invention has particular application to a plastic BGA (PBGA) package.

### BACKGROUND OF THE INVENTION

1. Field of the Invention

This invention relates generally to integrated circuits. More particularly, it relates to an improvement of the underside structure on what has become known as a plastic ball grid array (Plastic BGA, or PBGA) or overmolded pad array carrier (OMPAC).

2. Background of Related Art

The ball grid array (BGA) or overmolded pad array carrier (OMPAC) package has seen a rapid increase in popularity due to its motherboard space efficiency as well as good thermal and electrical performance. Originally developed in the late 1980s, the pin density (i.e., the number of electrical connections that can be made between the printed circuit board (PCB) and the integrated circuit carried in the BGA package) has grown tremendously.

The Joint Electron Device Engineering Council (JEDEC) adopted standard PBGA body sizes in August of 1993, ranging from 7 to 50 mm with pitches of 1.00, 1.27 and 1.50 mm. These pitch and body size combinations result in pin counts ranging from 16 to 2401 pins.

With PBGA packaging comes a new challenge for circuit board manufacturers installing integrated circuits contained within the PBGA packages. In particular, the placement and reflow of solder ball preforms to form bumps on the package bottomside is a new required assembly step with PBGA packages.

FIG. 4 is a cross-sectional depiction of a typical BGA package.

In particular, as shown in FIG. 4, a conventional BGA package 500 is shown assembled to a suitable printed circuit board (PCB) such that solder balls 504 are reflowed between pads etched onto the surface of the PCB 502 and associated solder pads 506 on the underside of the BGA package 500. Also shown are wire bond wires 508, an epoxy overmold (or glob-top) 510, thermal/ground vias 512, the silicon die or integrated circuit chip 514 and adhesive 516 used to attach the silicon die 514 to the BT/GLASS BGA substrate 520 constituting the lower portion of the BGA package 500. Routing vias 522 are variously formed on the BGA substrate 520. The pitch, or spacing of the depicted solder balls and solder pads on the BGA substrate 520 of the BGA package 500 is 1.0, 1.27, or 1.5 mm. Typical thickness of the BGA substrate 520 is approximately 0.36 mm to 0.60 mm, and typical height of the epoxy overmold 510 is about 0.8 to 1.2 mm. Ideal separation between the BGA substrate 520 and the PCB 502 to which it is mounted is from 0.4 mm to 0.6 mm.

A conventional Plastic BGA package 500 is based on a glass reinforced organic substrate 520 made of several possible materials, the most common of which is Bismalemide Triazene (BT) epoxy resin developed by Mitsubishi Gas Chemical. Because of its excellent high temperature properties (high Tg, excellent heat resistance, high temperature stability), BT resin is well suited for a semiconductor packaging application where various high temperature excursions are associated with the required assembly processes. These high temperature processes may include die-bonding and cure, wire-bonding, encapsulation and cure, solder ball attach reflow, cleaning and drying. Elevated temperature exposure following packaging may also be encountered during high temperature testing, burn-in, repeated baking cycles to remove moisture, and finally surface mount assembly to a desired PCB.

The BT/glass substrate 520 is generally processed in a strip which can consist of from three to twelve or more package sites. The nominal strip thickness currently used is 0.36 mm (including BT/glass core, solder mask and copper feature thicknesses) for double-sided substrates and 0.60 mm for four layer substrates.

A silicon die (i.e., the integrated circuit or IC) 514 is die-bonded and wire-bonded to the die pad on 520 or flag at each die site on the strip similar to chip on board (COB) manufacturing procedures. This is followed by an encapsulation of the sites with a filled epoxy overmold 510.

The encapsulation may be performed with a cavity mold resulting in a formed molded body shape or with a glob-top liquid encapsulant that is possibly preceded by the application of a dam for containment of the glob-top material. Whichever process is used, careful selection of encapsulant materials to minimize substrate and therefore package warpage is desired.

Once the BGA package 500 is overmolded, solder ball preforms 504 with a typical diameter of, e.g., 0.75 mm (for 1.27 and 1.50 mm pitch) are placed on the solder pads 506 on the strip bottomside, and reflowed to form bumps. These melting solder bumps 504 formed on the PBGA package 500 are sometimes referred to as a controlled collapse chip carrier connection, or C5 joint.

After solder ball reflow, it may be necessary to clean the BGA package 500 to remove flux residue. Finally, following cleaning, the individual BGA packages 500 are singulated from the strip by any one of several methods.

The JEDEC standards organization has promulgated standards regarding BGA packaging. With respect to warpage, the JEDEC standards indicate that the worst-case co-planarity, which is largely a direct result of any warpage, is currently preferably no more than 0.2 mm independent of component body size. Additionally, thicker substrates than those discussed above have been proposed to further increase package flatness, especially for larger packages.

FIG. 5 shows a conventional, warped BGA package 500 showing compressed solder balls 504a, particularly towards the edge and corners of a Plastic BGA substrate 520. FIG. 5 shows how solder balls closer to the corners will compress excessively and potentially short if the BGA package 500 is allowed to warp and compress corners, and perhaps even contact the PCB 502.

As shown, solder balls 504a located closer to the edges and/or corners of a conventional BGA package 500 tend to be more compressed beyond that which is desired, pressing the PBGA substrate 520 of the GBA package 500 too close to the PCB 502 onto which it is ultimately mounted, causing a danger of, or resulting directly in, an electrical short 507 produced between two adjacent, excessively compressed solder balls 504a. Such shorts in packages lowers yields and lowers product reliability, particularly through the manufacturing stage, increasing costs and rework.

Conventional techniques to prevent warpage generally center around the development of new mold compounds having reduced warpage characteristics. Nevertheless, to date all conventional mold compound formulations currently available nevertheless warp to some extent. What the present inventors have appreciated is that this warpage results in corner BGA ball shorting, or at a minimum reduces manufacturing reliability because of an excessive number of devices in which corner PBGA ball shorting occurs.

There is a need for a BGA package design that better avoids or even prevents altogether solder-ball shorting caused by warpage.

### SUMMARY OF THE INVENTION

In accordance with the principles of the present invention, in a ball grid array (BGA) package, the solder ball side of the BGA package comprises a plurality of solder balls, and at least one tab support extending in a direction toward a PCB to which the BGA package will ultimately be mounted. The at least one tab support prevents excessive compression of a solder ball in a vicinity of the at least one tab support.

In accordance with another aspect of the present invention, a method of preventing solder ball shorting in a BGA package comprises providing a BGA substrate for attachment of a plurality of solder balls to a BGA package. At least one tab support is provided on a solder ball side of the BGA substrate. The at least one tab support has a height corresponding to a desired distance between the BGA substrate and a PCB to which the BGA package will be mounted, in a mounted state. The at least one tab support prevents excessive compression of ones of the plurality of solder balls in a vicinity of the at least one tab support.

### BRIEF DESCRIPTION OF THE DRAWINGS

Features and advantages of the present invention will become apparent to those skilled in the art from the following description with reference to the drawings, in which:

FIG. 1 shows a side view of a ball grid array (BGA) package with corner standoff tab supports mounted in corners of a solder ball side of a BGA substrate to prevent solder ball shorting due to warpage, in accordance with the principles of the present invention.

FIG. 2 shows an underside view of the BGA package with standoff tab supports molded in corners of a solder ball side of a BGA substrate to prevent solder ball shorting due to warpage shown in FIG. 1.

FIG. 3 shows an underside view of the BGA package with standoff tab supports molded in edges of a solder ball side of a BGA substrate to prevent solder ball shorting due to warpage, in accordance with another embodiment of the present invention.

FIG. 4 is a cross-sectional depiction of a typical BGA package.

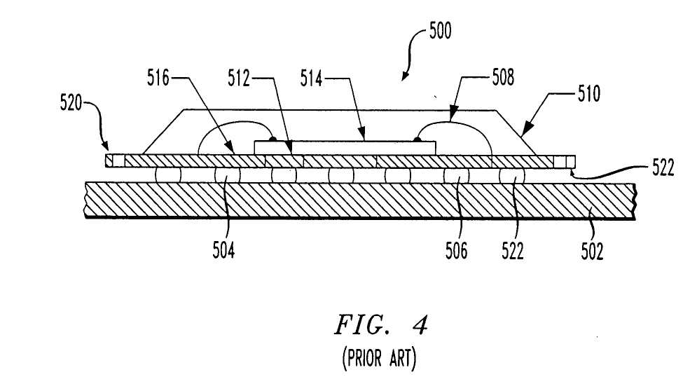

FIG. 5 shows a conventional, warped BGA package showing compressed and shorted solder balls, particularly towards the edge and corners of a BGA substrate.

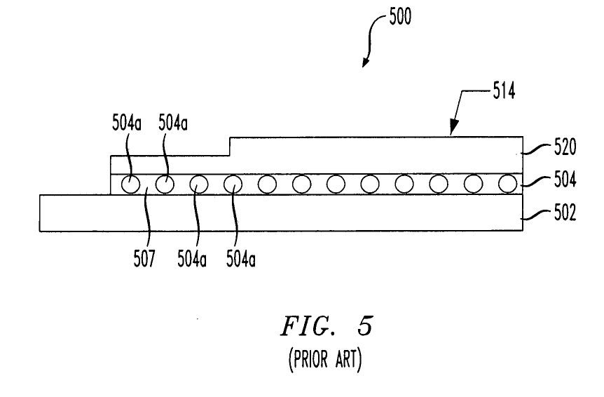

### DETAILED DESCRIPTION OF ILLUSTRATIVE EMBODIMENTS

In the real-world, overmolded BGA packages warp during high temperature manufacturing processes, e.g., particularly due to the high temperatures associated with a solder reflow process intended to melt each of the solder balls and cause an electrical path to be formed with respect to each individual ball. This warpage increases with higher reflow temperatures and is severe enough to cause the corner BGA balls to bridge together, causing electrical solder shorts between the BGA balls.

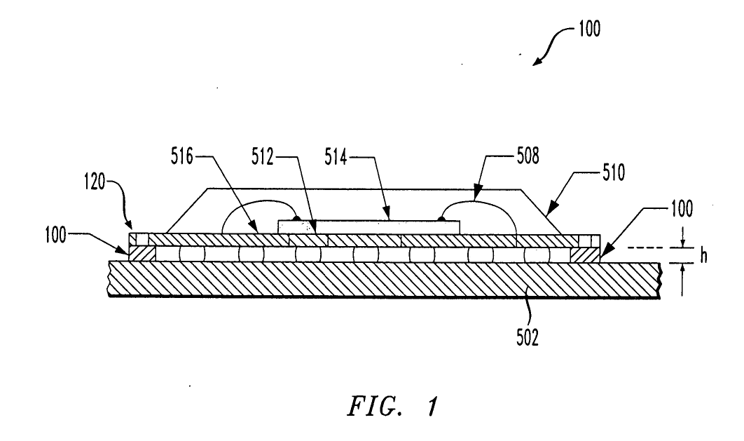

The present invention includes supporting features built onto the underside, or solder ball side of the BGA package substrate. In an alternative embodiment, the tab supports may be mounted to the PCB to which the BGA package will be mounted, preferably in areas corresponding to the corners of the BGA package when mounted, and/or to the edges of the BGA package. The tab supports are preferably sized (h in FIG. 1) in a height direction to avoid or prevent a warped corner or edge of a BGA substrate from excessively pressing down on the solder balls when warping occurs, most often during the high temperature solder-reflow process.

The physical pressure of each of the solder balls, working against the upward pressure caused by the use of the tab supports, tend to prevent future compression of the solder balls during high temperature processing.

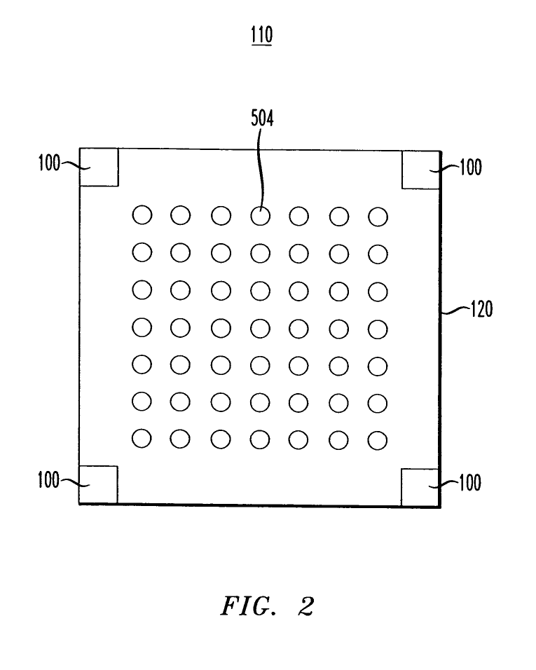

FIGS. 1 and 2 show exemplary placement of corner tab supports against corners of a BGA package, in accordance with the principles of the present invention. While the present invention is shown and described with respect to a Plastic BGA (PBGA) package, the principles of the present invention relate equally to other forms of PBGA packaging other than plastic.

In particular, FIG. 1 shows a side view of a ball grid array (BGA) package 110 with corner standoff tab supports 100 molded onto corners of a solder ball side of a BGA substrate 120 to prevent solder ball shorting due to warpage, in accordance with the principles of the present invention.

The exemplary tabs in the given embodiments comprise small standoff tabs 100 placed in all four corners of the lower substrate 120 of a BGA package 110.

The corner tab supports 100 are preferably incompressible at high temperatures such as is experienced during a solder reflow process. The corner tab supports 100 prevents a warped GBA package body (which using current component materials ALWAYS warps, at least to some extent) from contacting the printed wiring board 502. This in turn prevents the solder balls 504, once heated and in a melted form, from compressing excessively to the point that they touch or otherwise short together.

Use of corner tab supports 100 on an underside, or solder ball side of a BGA package 110 in accordance with the principles of the present invention will prevent compression of solder balls 504 in a vicinity of the tab support 100 from compressing beyond a given amount equal to the height of the corner tab support 100, i.e., the length of the protrusion of the tab support 100 from the underside of the BGA substrate 120 of the BGA package 110.

FIG. 2 shows an underside view of the BGA package with standoff tab supports molded in corners of a solder ball side of a BGA substrate to prevent solder ball shorting due to warpage shown in FIG. 1.

The particular shape of the tab supports 100 is insignificant, so long as they allow reflow processes to take place there around. For instance, the exemplary tab supports 100 are shown to have a square cross-section. Rectangular, circular, oval, or polygonal cross-sectional shapes are equally possible, as is the use of a glob of hardening material, e.g., a glob of epoxy.

Moreover, tab supports 100 in accordance with the present invention may be made from any suitably heat resistant material. Exemplary materials include, but are not limited to, dispensed adhesive, molded plastic tabs, corner or edge overmolded plastic tab supports, attached metal or plastic tab supports, or metal tabs which are extruded or otherwise incorporated on a BGA product to extend beyond the substrate to support the substrate in the event of warpage, e.g., caused during the reflow or other high temperature process.

Significant advantages results from the use of corner or edge tab supports in a BGA package 110 in accordance with the principles of the present invention. For instance, solder ball interconnects on BGA packages will not solder-ball-short as a result of warpage. Moreover, depopulating or non-use of solder balls nearest to corners and/or edges to increase reliability is no longer necessary, increasing connection density in a given BGA package.

Over molded tabs 100 can be designed into mold fixtures and easily incorporated into the over molding process. Furthermore, external plastic or metal tabs could be attached to the substrate 120 before or after attachment of the solder balls 504.

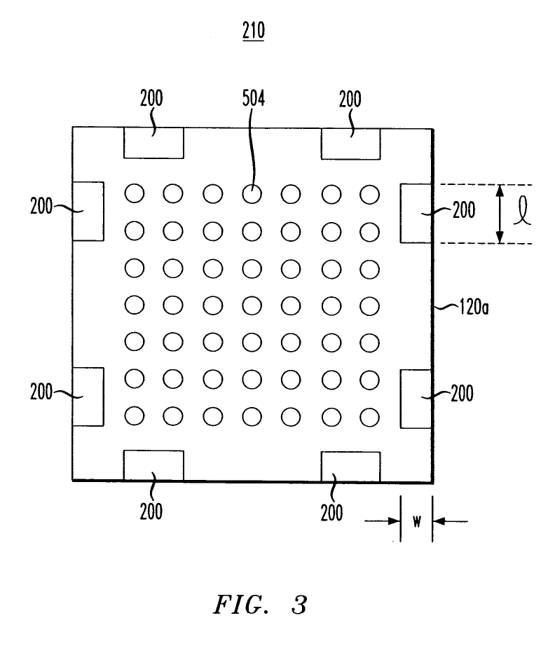

FIG. 3 shows an underside view of the BGA package with standoff tab supports molded in edges of a solder ball side of a BGA substrate to prevent solder ball shorting due to warpage, in accordance with another embodiment of the present invention.

In particular, as shown in FIG. 3, tab supports 200 are extruded into edge regions on the underside, or solder ball side of the substrate 120a. The edge tabs 200 may be of any particular length l, but the length l is preferably short enough to allow cleaning fluids to flow freely through the underside of the BGA package 210 once it is mounted onto a PCB 502. The width w of the tab supports 200 should also be sized to freely allow cleaning fluids to pass through the underside of the BGA package 210, yet be thick enough to provide sufficiently sturdy support of the tab to the underside of the BGA package 210.

While the invention has been described with reference to the exemplary embodiments thereof, those skilled in the art will be able to make various modifications to the described embodiments of the invention without departing from the true spirit and scope of the invention.

1. In a ball grid array (BGA) package, the solder ball side of said BGA package comprising:
a plurality of solder balls; and
at least one tab support extending in a direction toward a PCB to which said BGA package will ultimately be mounted;
wherein said at least one tab support prevents excessive compression of a solder ball in a vicinity of said at least one tab support.

2. In a ball grid array (BGA) package according to claim 1, wherein said at least one tab support comprises:
four corner tab supports, each of said four corner tab supports being mounted in a respective corner of said solder ball side of said BGA package.

3. In a ball grid array (BGA) package according to claim 2, wherein said at least one tab support further comprises:
four edge tab supports, each of said four edge tab supports being mounted on a respective outer edge corner of said solder ball side of said BGA package.

4. In a ball grid array (BGA) package according to claim 1, wherein said at least one tab support comprises:
four edge tab supports, each of said four edge tab supports being mounted on a respective outer edge corner of said solder ball side of said BGA package.

5. In a ball grid array (BGA) package according to claim 1, wherein:
said BGA package is a plastic BGA (PBGA) package.

6. A method of preventing solder ball shorting in a BGA package, comprising:
providing a BGA substrate for attachment of a plurality of solder balls to a BGA package; and
providing at least one tab support on a solder ball side of said BGA substrate, said at least one tab support having a height corresponding to a desired distance between said BGA substrate and a PCB to which said BGA package will be mounted, in a mounted state;
wherein said at least one tab support prevents excessive compression of ones of said plurality of solder balls in a vicinity of said at least one tab support.

7. The method of preventing solder ball shorting in a BGA package according to claim 6, wherein:
said at least one tab support is molded into said BGA substrate.

8. The method of preventing solder ball shorting in a BGA package according to claim 6, wherein:
said at least one tab support is formed from a dispensed glob of adhesive material onto said BGA substrate.

9. The method of preventing solder ball shorting in a BGA package according to claim 6, wherein:
said at least one tab support is overmolded onto a respective at least one edge of said BGA substrate.

10. The method of preventing solder ball shorting in a BGA package according to claim 6, wherein:
said at least one tab support is formed from metal and attached to said BGA substrate.

11. The method of preventing solder ball shorting in a BGA package according to claim 6, wherein:
said at least one tab support is formed from plastic.

12. The method of preventing solder ball shorting in a BGA package according to claim 6, wherein:
at least four tab supports are provided.

13. The method of preventing solder ball shorting in a BGA package according to claim 6, wherein:
said BGA package is a plastic BGA (PBGA) package.

14. Apparatus for preventing solder ball shorting in a BGA package, comprising:
BGA substrate means for attachment of a plurality of solder balls to a BGA package; and
at least one tab support means on a solder ball side of said BGA substrate, for preventing excessive compression of ones of said plurality of solder balls in a vicinity of said at least one tab support;
wherein said at least one tab support means has a height corresponding to a desired distance between said BGA substrate and a PCB to which said BGA package will be mounted, in a mounted state.

15. The apparatus for preventing solder ball shorting in a BGA package according to claim 14, wherein:
said at least one tab support means is molded into said BGA substrate means.

16. The apparatus for preventing solder ball shorting in a BGA package according to claim 14, wherein:
said at least one tab support means is formed from a dispensed glob of adhesive material onto said BGA substrate means.

17. The apparatus for preventing solder ball shorting in a BGA package according to claim 14, wherein:
said at least one tab support means is overmolded onto a respective at least one edge of said BGA substrate means.

18. The apparatus for preventing solder ball shorting in a BGA package according to claim 14, wherein:
said at least one tab support means is formed from metal and attached to said BGA substrate means.

19. The apparatus for preventing solder ball shorting in a BGA package according to claim 14, wherein:
said at least one tab support means is formed from plastic.

20. The apparatus for preventing solder ball shorting in a BGA package according to claim 14, wherein said at least one tab support means comprises:
at least four tab supports.

21. The apparatus for preventing solder ball shorting in a BGA package according to claim 14, wherein:
said BGA package is a plastic BGA (PBGA) package.

22. A method of preventing solder ball shorting in a BGA package, comprising:
providing a BGA substrate for attachment of a plurality of solder balls to a BGA package; and
providing at least one tab support on a PCB to which said BGA package will be mounted, for placement against a solder ball side of said BGA substrate, said at least one tab support having a height corresponding to a desired distance between said BGA substrate and said PCB, in a mounted state;
wherein said at least one tab support prevents excessive compression of ones of said plurality of solder balls in a vicinity of said at least one tab support.

23. The method of preventing solder ball shorting in a BGA package according to claim 22, wherein:
said at least one tab support is formed from a dispensed glob of adhesive material onto said PCB.

24. The method of preventing solder ball shorting in a BGA package according to claim 22, wherein:
said at least one tab support is formed from metal and attached to said PCB.

25. The method of preventing solder ball shorting in a BGA package according to claim 22, wherein:
said at least one tab support is formed from plastic.

26. The method of preventing solder ball shorting in a BGA package according to claim 22, wherein:
at least four tab supports are provided.
